(19) United States
(12) Patent Application Publication
(10) Pub. No.: US 2014/0175482 A1
(43) Pub. Date: Jun. 26, 2014

(54) LIGHT EMITTING DIODE PACKAGE WITH LIGHT REFLECTING CUP INTERNALLY SLANTED

(71) Applicant: ADVANCED OPTOELECTRONIC TECHNOLOGY, INC., Hsinchu Hsien (TW)

(72) Inventors: YAU-TZU JANG, Hsinchu (TW); PIN-CHUAN CHEN, Hsinchu (TW); LUNG-HSIN CHEN, Hsinchu (TW); HSING-FEN LO, Hsinchu (TW); WEN-LIANG TSENG, Hsinchu (TW); YU-LIANG HUANG, Hsinchu (TW)

(73) Assignee: ADVANCED OPTOELECTRONIC TECHNOLOGY, INC., Hsinchu Hsien (TW)

(21) Appl. No.: 13/963,324

(22) Filed: Aug. 9, 2013

(30) Foreign Application Priority Data
Dec. 22, 2012 (CN) 2012105617812

(51) Int. Cl. H01L 33/60

(52) U.S. Cl. CPC H01L 33/60
USPC 257/98

(57) ABSTRACT

An exemplary LED package includes a base, electrodes formed on the base, an LED chip electrically connecting the electrodes, and a reflecting cup mounted on the base and surrounding the LED chip therein. The reflecting cup includes a bottom surface and an inner surface recessed up from the bottom surface and slantwise oriented towards a top end of the reflecting cup. The reflecting cup is annular. The inner surface includes a reflecting portion slantwise extending from the top surface, and a transition portion extending downwardly from the reflecting portion. The transition portion defines a through hole therein. The reflecting portion defines a reflecting hole therein. An angle α is defined between the reflecting portion and an imaginary surface parallel to the bottom surface. An angle β is defined between the reflecting portion and the bottom surface. The angle β is larger than the angle α.

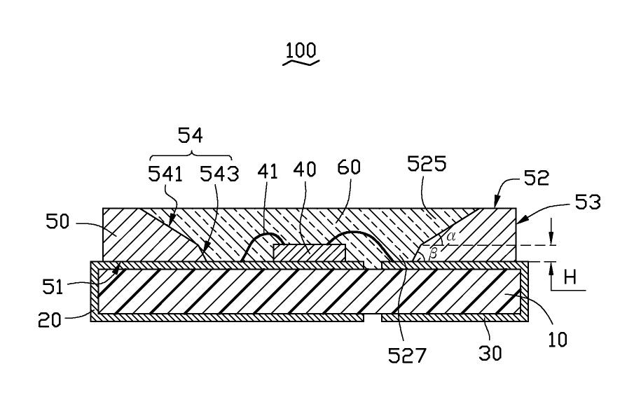

### BACKGROUND

1. Technical Field

The disclosure generally relates to a light emitting diode (LED) package having a light reflecting cup which is internally slanted such that the quality of the light reflecting cup formed by molding is high and the light reflecting cup gives the LED package stable and reliable performance.

2. Description of Related Art

A conventional LED package includes two spaced electrodes, an LED chip mounted on one of the electrodes and electrically connecting the electrodes, and a reflecting cup mounted on the electrodes and surrounding the LED chip therein. The reflecting cup is manufactured by injection molding. A mold for receiving molding material to form the reflecting cup has a profile the same as that of the reflecting cup. The reflecting cup includes an annular bottom surface mounted on the electrodes, an outer surface extending up from an outer edge of the bottom surface, a top surface parallel to the bottom surface, and an inner surface recessed from a center portion of the top surface. The inner surface is a smooth reflecting surface, which defines a receiving hole of the reflecting cup. The receiving hole receives the LED chip therein, and the inner surface reflects light emitted from the LED chip.

In order for the reflecting cup to reflect the light to a large area outside the LED package, the inner surface may extend down close to the bottom surface. In such case, a three-dimensional area inside the reflecting cup between a bottom end of the inner surface and a bottom end of the reflecting cup corresponding to the bottom surface is prone to be shallow (as viewed from a lateral side of the LED package), and the inner surface at the shallow area typically has an arcuate transverse cross-section. Thus, a three-dimensional area inside the mold corresponding to the shallow area of the reflecting cup is prone to be shallow, and an inner circumferential wall of the mold at the shallow area typically has an arcuate transverse cross-section. As a result, in fabrication of the reflecting cup, air is prone to be trapped in an inmost annular part of the shallow area of the mold where the inner circumferential wall of the mold adjoins a bottom annular wall of the mold. That is, a plurality of air bubbles is liable to be formed in the molding material. Accordingly, a plurality of burrs or other irregularities is formed on the inner surface of the reflecting cup at the shallow area and an inmost annular part of the bottom surface of the reflecting cup. Such burrs or other irregularities may adversely affect the performance of the LED package.

What is needed is an LED package which can overcome or at least mitigate the problems of the related art.

### BRIEF DESCRIPTION OF THE DRAWING

The drawing is a schematic, side cross-sectional view of an LED package according to an exemplary embodiment of the present disclosure.

### DETAILED DESCRIPTION

An embodiment of an LED package in accordance with the present disclosure will now be described in detail below and with reference to the drawing.

Referring to the drawing, an LED package 100 in accordance with an exemplary embodiment of the present disclosure includes a base 10, a first electrode 20 and a second electrode 30 spaced from and aligned with each other and mounted on the base 10, an LED chip 40 mounted on the first electrode 20 and electrically connecting the first electrode 20 and the second electrode 30, a reflecting cup 50 formed on the first electrode 20 and the second electrode 40 and surrounding the LED chip 40 therein, and an encapsulation layer 60 filled in the reflecting cup 50. Alternatively, in other embodiments, the LED chip 40 and the reflecting cup 50 are directly formed on the base 10.

The base 10 is made of material having good heat dissipation efficiency, and includes a flat top surface and a flat bottom surface parallel to the top surface. The first electrode 20 is formed corresponding to a left end of the base 10. Specifically, the first electrode 20 is U-shaped and extends from a middle portion of the top surface to a left end of the top surface, down a lateral side edge of the base 10 to a left end of the bottom surface, and from the left end of the bottom surface to a middle portion of the bottom surface. In the illustrated embodiment, the first electrode 20 is symmetrical about a center horizontal plane thereof. The second electrode 30 is formed corresponding to a right end of the base 10. Specifically, the second electrode 30 is U-shaped and extends from approximately a middle portion of the top surface to a right end of the top surface, down an opposite lateral side edge of the base 10 to a right end of the bottom surface, and from the right end of the bottom surface to approximately a middle portion of the bottom surface. In the illustrated embodiment, the second electrode 30 is symmetrical about a center horizontal plane thereof.

The LED chip 40 is directly formed on a top surface of the first electrode 20, and is electrically connected to the first electrode 20 and the second electrode 30 by wires 41.

The reflecting cup 50 is annular, and is manufactured by injection molding or insert molding. When the reflecting cup 50 is manufactured, a mold for receiving a molding material is provided. The mold has a profile which is the same as that of the reflecting cup 50. The reflecting cup 50 includes a generally annular bottom surface 51, a generally annular top surface 52 parallel to the bottom surface 51, a peripheral outer surface 53 interconnecting outer edges of the bottom surface 51 and the top surface 52, and a peripheral inner surface 54 interconnecting inner edges of the bottom surface 51 and the top surface 52. The outer surface 53 is perpendicular to the bottom surface 51 and the top surface 52. The inner surface 54 includes an upper reflecting portion 541 and a lower transition portion 543. The reflecting portion 541 is slantwise recessed from a central portion of the top surface 52. The transition portion 543 slantwise extends from a bottom end of the reflecting portion 541. The bottom surface of the reflecting cup 50 is mounted on the first and second electrodes 20, 30.

The reflecting portion 541 is smooth, to reflect light emitted from the LED chip 40. The reflecting portion 541 defines a reflecting hole 525 therein, and a transverse cross-section of the reflecting hole 525 defines an isosceles trapezoidal shape. An aperture of the reflecting hole 525 decreases from a top end thereof at the top surface 52 to a bottom end thereof near the bottom surface 51 and corresponding to a top end of the transition portion 543. Thus, the reflecting hole 525 is in the form of a tapered disk-shaped space. An angle α is defined between a transverse cross-section of the reflecting portion 541 and an imaginary surface (shown in a broken line in the drawing) parallel to the bottom surface 51. The angle α is not less than 15 degrees and not larger than 30 degrees, to make the reflecting portion 541 reflect the light emitted from the LED chip 40 to an enlarged area (compared to a conventional LED package) outside the LED package 100. Thus the LED package 100 illuminates the enlarged area.

The transition portion 543 is smooth, and surrounds the LED chip 40. The transition portion 543 defines a through hole 527 therein, with the through hole 527 receiving the LED chip 40. A transverse cross-section of the through hole 527 defines an isosceles trapezoidal shape. An aperture of the through hole 527 decreases from a top end thereof adjacent to the reflecting hole 525 to a bottom end thereof adjacent to the first and second electrodes 20, 30. Thus, the through hole 527 is in the form of a tapered disk-shaped space. The through hole 527 is coaxial with the reflecting hole 525 and communicates with the reflecting hole 525.

An angle β is defined between a transverse cross-section of the transition portion 543 and the bottom surface 51. The angle β is larger than the angle α. As a result, in fabrication of the reflecting cup 50, molding material is apt to more easily completely fill an inmost annular part of a three-dimensional shallow area of a corresponding mold where an inner circumferential wall of the mold at the shallow area adjoins a bottom annular wall of the mold. That is, during the molding process, air in the mold is able to be entirely exhausted from the mold and not become trapped in the mold. When no air bubbles are formed in the molding material, the bottom surface 51 and the transition portion 543 are both smooth, with substantially no burrs or other irregularities. In this embodiment, the angle β is not less than 35 degrees and not larger than 45 degrees. A distance H between the bottom surface 51 and an inner peripheral joint of the reflecting portion 541 and the transition portion 543 is less than 0.01 millimeters, to help ensure that the air of the mold can be entirely exhausted. A depth of the through hole 527 is not less than a height of the LED chip 40 protruding from the first electrode 20.

The encapsulation layer 60 is made of transparent or translucent silicone, which fills the reflecting hole 525 and the through hole 527, and also fills a gap between the first and second electrodes 20, 30. Thus, the encapsulation layer 60 encapsulates the LED chip 40 therein to protect the LED chip 40. Alternatively, the encapsulation layer 60 is a mixture of silicone and phosphor powders evenly distributed in the silicone.

In summary, because the transition portion 543 is located between the reflecting portion 541 and the bottom surface 51, and because the angle β is larger than the angle α, in fabrication of the reflecting cup 50, the molding material easily completely fills the corresponding area of the mold. Thereby, air is substantially entirely exhausted from the mold, so that formation of air bubbles in the molding material is avoided. Therefore the inner surface 54 and the bottom surface 51 of the reflecting cup 50 are smooth, to provide the reflecting cup 50 with stable, reliable and efficient performance.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED) package comprising:
a base;
a plurality of electrodes formed on the base;
an LED chip electrically connecting the electrodes; and
a reflecting cup mounted on the base and surrounding the LED chip therein, the reflecting cup comprising a bottom surface, a top surface substantially parallel to the bottom surface, an outer surface interconnecting outer edges of the bottom surface and the top surface, and an inner surface interconnecting inner edges of the top surface and the bottom surface;
wherein the inner surface comprises a reflecting portion and a transition portion, the reflecting portion extends slantwise downwardly from the top surface, the transition portion extends slantwise downwardly from the reflecting portion, the transition portion surrounds and defines a through hole of the reflecting cup, the LED is received in the through hole, the reflecting portion is positioned to reflect light emitting from the LED chip, an angle α is defined between a transverse cross-section of the reflecting portion and an imaginary surface parallel to the bottom surface, an angle β is defined between a transverse cross-section of the transition portion and the bottom surface, and the angle β is larger than the angle α.

2. The LED package of claim 1, wherein the angle α is not less than 15 degrees and not larger than 30 degrees.

3. The LED package of claim 1, wherein the angle β is not less than 35 degrees and not larger than 45 degrees.

4. The LED package of claim 1, wherein the reflecting portion surrounds and defines a reflecting hole of the reflecting cup, and the through hole is coaxial with the reflecting hole and communicates with the reflecting hole.

5. The LED package of claim 4, wherein a transverse cross-section of the reflecting hole defines an isosceles trapezoidal shape, and an aperture of the reflecting hole decreases from a top end thereof at the top surface to a bottom end thereof adjacent to the through hole.

6. The LED package of claim 5, wherein a transverse cross-section of the through hole defines an isosceles trapezoidal shape, and an aperture of the through hole decreases from a top end thereof adjacent to the reflecting hole to a bottom end thereof adjacent to the electrodes.

7. The LED package of claim 1, wherein a distance H between the bottom surface and an inner peripheral joint of the reflecting portion and the transition portion is less than 0.01 millimeters.

8. The LED package of claim 1, wherein the LED chip is formed on a top surface of one of the electrodes, and a depth of the through hole is not less than a height of the LED chip protruding from the electrode.

9. The LED package of claim 1, wherein the electrodes are formed on the base and spaced from each other, the LED chip is mounted on one of the electrodes, and the bottom surface of the reflecting cup is mounted on the two electrodes.

10. The LED package of claim 1, wherein an encapsulation layer fills the through hole and the reflecting hole to encapsulate the LED chip therein.

11. The LED package of claim 10, wherein the encapsulation layer is made of silicone.

12. The LED package of claim 10, wherein the encapsulation layer is a mixture of silicone and phosphor powders evenly distributed in the silicone.

13. A light emitting diode (LED) package comprising:
a base;
a plurality of electrodes formed on the base;
an LED chip electrically connecting the electrodes; and
an annular reflecting cup mounted on the base and surrounding the LED chip therein, the reflecting cup comprising a top surface, a bottom surface, and an inner surface recessed up from the bottom surface, the inner surface slantwise oriented towards a top end of the reflecting cup and extending to the top surface of the reflecting cup;
wherein the inner surface comprises a reflecting portion and a transition portion, the reflecting portion extends slantwise downwardly from the top surface, the transition portion extends slantwise downwardly from a bottom end of the reflecting portion, the transition portion defines a through hole receiving the LED therein, the reflecting portion defines a reflecting surface to reflect light emitting from the LED chip, an included angle α is defined between the reflecting portion and an imaginary surface parallel to the bottom surface, an included angle β is defined between the transition portion and the bottom surface, and the angle β is larger than the angle α.

14. The LED package of claim 13, wherein the angle α is not less than 15 degrees and not larger than 30 degrees.

15. The LED package of claim 13, wherein the angle β is not less than 35 degrees and not larger than 45 degrees.

16. The LED package of claim 13, wherein the through hole is coaxial with the reflecting hole and communicates with the reflecting hole.

17. The LED package of claim 13, wherein a distance H between the bottom surface and an inner peripheral joint of the reflecting portion and the transition portion is less than 0.01 millimeters.

18. The LED package of claim 13, wherein a depth of the through hole is not less than a height of the LED chip protruding from the electrode.
